(19) United States
(12) Patent Application Publication
(10) Pub. No.: US 2026/0205041 A1
(43) Pub. Date: Jul. 16, 2026

(54) MOTOR CONTROLLER AND METHOD FOR ESTIMATING A MOTOR SHAFT ANGLE OR A MOTOR SHAFT ROTATION SPEED OF A MOTOR

(71) Applicant: Infineon Technologies AG, Neubiberg (DE)

(72) Inventors: Mihail Jefremow, Augsburg (DE); Jürgen Schäfer, Oberhaching (DE); Arndt Voigtländer, Antdorf (DE); Ghaith Amri, München (DE)

(21) Appl. No.: 19/450,064

(22) Filed: Jan. 15, 2026

(30) Foreign Application Priority Data
Jan. 16, 2025 (DE) 102025101522.8

(51) Int. Cl. H02P 23/12; H02P 6/17; H02P 23/00; H02P 23/14

(52) U.S. Cl. CPC H02P 23/12; H02P 6/17; H02P 23/0018; H02P 23/14; H02P 2207/05

(57) ABSTRACT

According to various embodiments, a motor controller is described, including an estimation circuit configured to implement a state observer and an input configured to receive measurements representing a sequence of motor shaft angles of a motor and to supply the measurements to the state observer, wherein the estimation circuit is configured to perform motor shaft angle or motor shaft rotation speed estimation by generating, by means of the state observer, a time series representing motor shaft angle estimates, motor shaft rotation speed estimates or motor shaft angle estimation errors from the measurements, filtering the generated time series by a machine learning model having an autoencoder architecture and generating one or more estimates of the motor shaft angle or the motor shaft rotation speed from the filtered time series.

### REFERENCE TO RELATED APPLICATION

This Application claims the benefit of German Application number 102025101522.8, filed on January 16, 2025, the contents of which are hereby incorporated by reference in their entirety.

### TECHNICAL FIELD

The present disclosure relates to motor controllers and methods for estimating a motor shaft angle or a motor shaft rotation speed of a motor.

### BACKGROUND

A state observer, e.g. a Luenberger observer, can be used to estimate the angular position and angular speed of an electric motor for motor control, e.g. in an electric car. For this, the state observer receives measurement signals such as a sine signal and a cosine signal from a resolver attached to a motor shaft of the motor. To enable the state observer to provide an estimate of sufficient accuracy, the measurement signals should be free of noise (disturbances) which, however, requires the provision of a sensor (e.g. resolver) of high quality. However, this may not be desirable for the respective (e.g. electric car) manufacturer for cost reasons. Accordingly, robust state observers are desirable, i.e. state observers which are able to handle noisy measurement signals, i.e. can provide accurate estimates even when supplied with poor measurement signals.

According to various embodiments, a motor controller is provided, comprising an estimation circuit configured to implement a state observer and an input configured to receive measurements representing a sequence of motor shaft angles of a motor and to supply the measurements to the state observer, wherein the estimation circuit is configured to perform motor shaft angle or motor shaft rotation speed estimation by generating, by means of the state observer, a time series representing motor shaft angle estimates, motor shaft rotation speed estimates or motor shaft angle estimation errors from the measurements, filtering the generated time series by a machine learning model having an autoencoder architecture and generating one or more estimates of the motor shaft angle or the motor shaft rotation speed from the filtered time series.

According to a further embodiment, a method for estimating a motor shaft angle or a motor shaft rotation speed of a motor according to the above motor controller is provided.

### BRIEF DESCRIPTION OF THE DRAWINGS

In the drawings, similar reference characters generally refer to the same parts throughout the different views. The drawings are not necessarily to scale, emphasis instead generally being placed upon illustrating the principles of the invention. In the following description, various aspects are described with reference to the following drawings, in which:

FIG. 1 shows a motor control arrangement according to an embodiment.

FIG. 2 shows a resolver-to-digital converter according to an embodiment.

FIG. 3 shows a first example of a machine-learning model being used in an estimation of motor shaft angle or motor shaft angle rotation speed.

FIG. 4 shows a second example of a machine-learning model being used in an estimation of motor shaft angle or motor shaft angle rotation speed.

FIG. 5 shows a third example of a machine-learning model being used in an estimation of motor shaft angle or motor shaft angle rotation speed.

FIG. 6 shows a fourth example of a machine-learning model being used in an estimation of motor shaft angle or motor shaft angle rotation speed.

FIG. 7 shows an example of a machine learning model, specifically a neural network, corresponding to the autoencoders in the examples of FIGS. 3 to 6.

FIG. 8 illustrates results of an application of a machine-learning model being used in an estimation of motor shaft angle or motor shaft angle rotation speed.

FIG. 9 illustrates further results of an application of a machine-learning model being used in an estimation of motor shaft angle or motor shaft angle rotation speed.

FIG. 10 shows a motor controller according to an embodiment.

FIG. 11 shows a flow diagram illustrating a method for estimating a motor shaft angle or a motor shaft rotation speed of a motor according to an embodiment.

### DESCRIPTION

The following detailed description refers to the accompanying drawings that show, by way of illustration, specific details and aspects of this disclosure in which the invention may be practiced. Other aspects may be utilized and structural, logical, and electrical changes may be made without departing from the scope of the invention. The various aspects of this disclosure are not necessarily mutually exclusive, as some aspects of this disclosure can be combined with one or more other aspects of this disclosure to form new aspects.

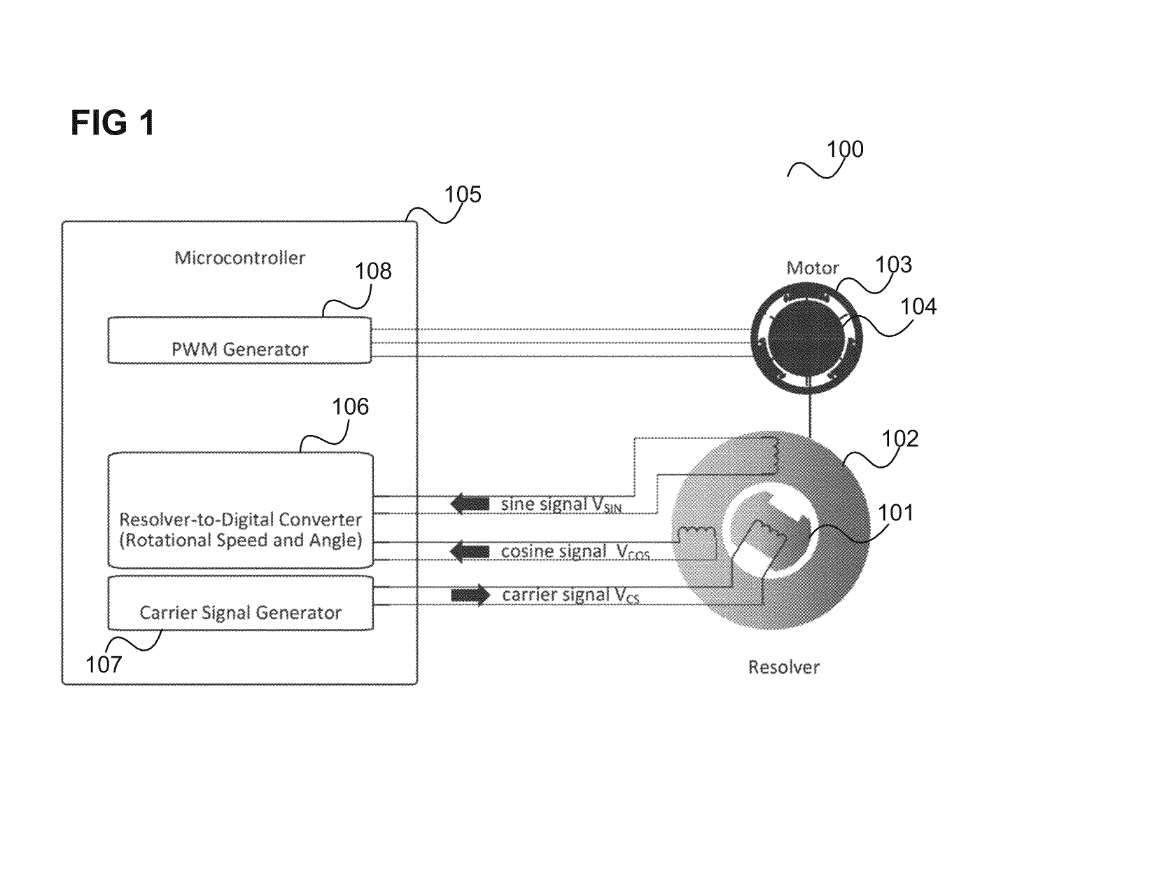

FIG. 1 shows a motor control arrangement 100 according to an embodiment.

The rotor 101 of a resolver 102 is attached to a motor shaft driven by a motor 103 (e.g. a permanent magnet synchronous motor (PMSM)) such that the angular position (i.e. angle) and the rotational speed of the resolver rotor 101 corresponds to the motor rotational speed and the angular position of the motor rotor 104.

The motor 103 is controlled by a microcontroller 105 (operating as motor controller) comprising a resolver-to-digital converter 106 (receiving output signals from the resolver 102), a carrier signal generator 107 (supplying the resolver rotor 101 with a carrier signal) and a PWM (pulse width modulation) generator 108.

During operation, the carrier signal generator 107 generates a carrier signal for output to the resolver 102. The resolver 102 is an electrical transformer that measures a rotational angle of the motor shaft driven by the motor 103. The resolver 102 has three coil windings: a primary winding supplied with the carrier signal and two secondary windings which output measurement signals, referred to as a sine signal and a cosine signal. The secondary windings are mounted 90° apart from each other in relation to the motor shaft. The primary winding is mounted on the resolver rotor 101 (and thus on the motor shaft) and in operation is excited by the carrier signal which is applied thereto. As the motor shaft rotates, the excited primary winding induces voltages in the secondary windings varying sinusoidally, thereby generating the sine signal and the cosine signal. The sine and the cosine signal are amplitude-modulated versions of the carrier signal with (ideally) a sine waveform and a cosine waveform as envelope, respectively. The resolver-to-digital converter 106 uses the sine signal and the cosine signal to determine an angular position θ of the motor shaft (according to sine θ/cosine θ=tangent θ) and, by considering the change of angular position over time, a rotational speed of the motor shaft.

The microcontroller 105 controls the motor via PWM, i.e. by controlling the PWM generator 108 to output PWM signals, e.g. according to a desired acceleration and supplies the PWM signals to the motor (e.g. via an eGTM (Enhanced Gate Driver Module) to a IGBT (Insulated Gate Bipolar Transistor) hybrid pack of the motor) to control the motor accordingly.

The microcontroller 105 may for example perform space vector PWM. This may include field-oriented control (FOC) using measurements of the average current through the motor windings as input (in addition to the range and speed information provided by the resolver-to-digital converter 106.

So, the motor control arrangement 100 forms a control loop for controlling the motor according to closed-loop control where a control signal (PWM signals for the three phases of the motor) is determined by the microcontroller (i.e. motor controller) based on measurements (sine signal and cosine signal and possibly average current measurements) and thus adapted to a feedback path (providing the measurements). In the following, an example for the structure and functionality of the resolver-to-digital converter 106 is described.

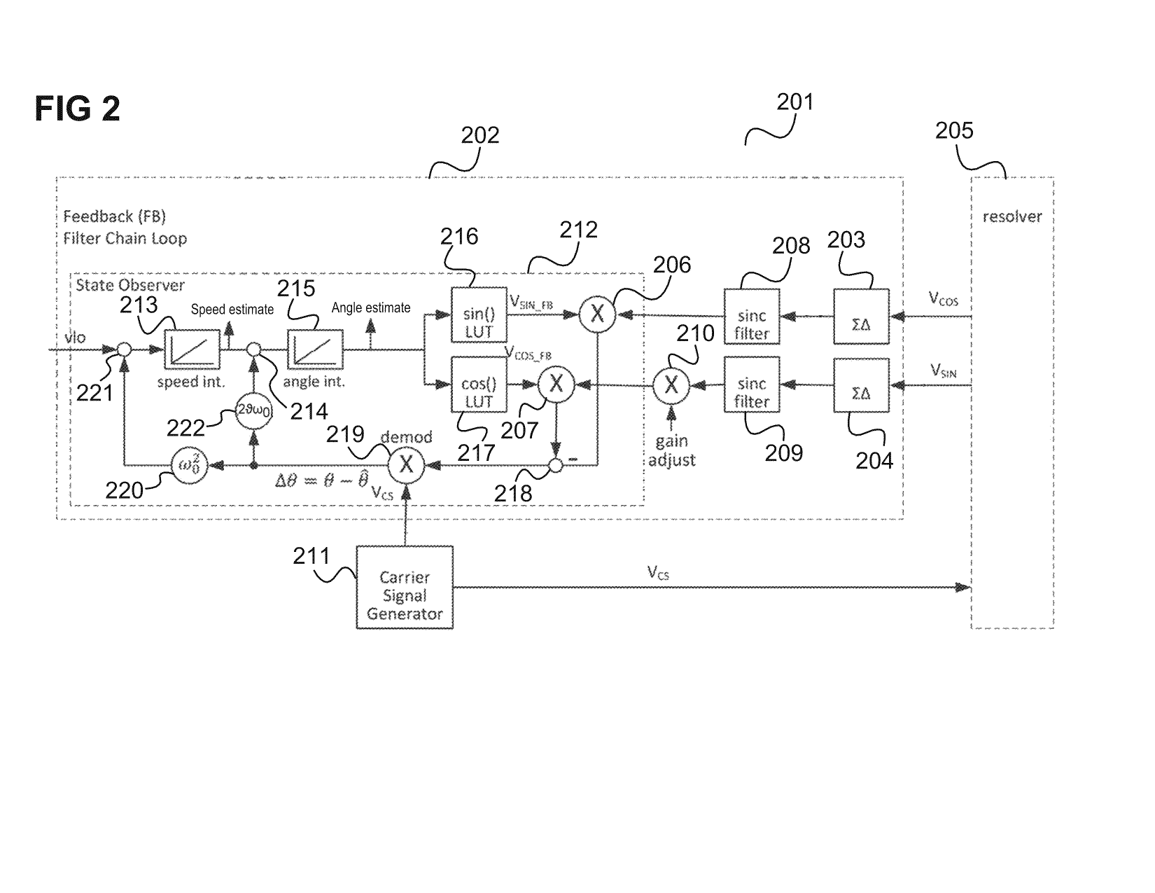

FIG. 2 shows a resolver-to-digital converter 201 according to an embodiment.

The resolver-to-digital converter 201 may for example be implemented in software on a CPU of the microcontroller 105 or on a digital signal processor of the microcontroller 105, e.g. a CDSP (Converter Digital Signal Processor).

The resolver-to-digital converter 201 comprises a feedback (FB) filter chain loop 202 which provides a speed estimate and a range estimate and optionally a post-processor which performs post-processing before outputting the range estimate and speed estimate (e.g. to a CPU performing the PWM control as described above with reference to FIG. 1).

The FB filter chain loop 202 comprises a pair of analog-to-digital converters 203, 204 (e.g. delta-sigma analog-to-digital converters (DS-ADCs)) which provide digitized versions of the sine and cosine signal (i.e. time series of, e.g. 16-bit, samples of the since and cosine signal, respectively) provided by the resolver 205 (corresponding to the resolver 102).

Optionally, the digitized cosine signal may be processed by a first sinc filter 208 before supplying it to a first mixer 206 and the digitized sine signal may be processed by a second sinc filter 209 and a gain adjuster (multiplier) 210 by a certain gain before supplying it to a second mixer 207.

So, the pair of DS-ADCs are configured to convert a pair of input sine and cosine signals VSIN, VCOS received from the resolver 205 as described above with reference to FIG. 1 from analog to digital. As mentioned above, the pair of input sine and cosine signals VSIN, VCOS are amplitude-modulated (AM) versions of a carrier signal VCS supplied by a carrier signal generator 211 which represent the rotation angle θ of the motor shaft. These input signals may be noisy. In particular, they are supposed to be phase shifted by 90 degrees with respect to each other, but due to the noise, they may not be.

The (optional) pair of sinc filters 208, 209 is configured to filter the pair of digital input sine and cosine signals VSIN, VCOS . A sinc filter is a type of low pass filter that removes high frequency components above a given cutoff frequency.

The first mixer 206 and the second mixer 207 are part of a state observer (e.g. a Luenberger observer) 212 of the FB filter chain loop 202. The state observer 212 is configured to estimate the rotation speed and the angular position (i.e. rotation angle) of the motor shaft from the digitized (and possibly filtered and gain-adjusted) sine signal and cosine signal supplied to it.

The state observer 212 comprises a rotation speed integrator 213 (configured to integrate a rotational acceleration to provide a rotational speed estimate), a first adder 214, a rotation angle integrator 215 (configured to integrate a rotational speed to provide an angle estimate), a sine look-up-table (LUT) 216 and a cosine LUT 217.

The rotation speed integrator 213 is configured to integrate an estimated rotation angle error signal Δθ of the motor shaft, and to output the rotation speed estimate. The rotation speed integrator 213 integrates its input over a carrier period to generate an envelope signal used for subsequent processing.

The first adder 214 is coupled between the rotation speed integrator 213 and the rotation angle integrator 215. It is configured to add the estimated rotation speed to a dampened version of 2ϑω0Δθ the estimated rotation angle error signal Δθ.

The rotation angle integrator 215 is configured to integrate the offset version of the estimated rotation speed provided by the first adder 214 and output the estimated rotation angle of the motor shaft.

The sine LUT 216 is configured to determine a feedback sine signal VSIN_FB according to the estimated rotation angle and the cosine LUT 217 is configured to determine a feedback cosine signal VCOS_FB according to the estimated rotation angle. The FB sine signal is mixed with the input cosine signal by the first mixer 206 the FB cosine signal is mixed with the input sine signal by the second mixer 207, to generate, by subtracting the outputs of the two mixers 206, 207 from each other by a subtractor 218, a (difference) signal which represents the estimated rotation angle error signal Δθ which can be seen as a difference between state observer’s estimate and the actual motor shaft angular position.

A demodulator 219 then demodulates the difference signal by multiplying it with the carrier signal VCS to output a demodulated version of the difference signal, i.e. the estimated rotational angle error signal Δθ. (It should be noted in this context that a small angle error Δθ can be approximated by sine(Δθ), which is a component resulting from the demodulation, and that higher frequency components are filtered out by the integrators 213 and 215).

The estimated rotational angle error signal is then gain-adjusted by two constants: A first multiplier 220 multiplies the estimated rotational angle error signal Δθ by ωo2 to output a gain-adjusted version of the rotational speed error signal, which a second adder 221 combines with a measured acceleration signal vlo to output the input to the rotational speed integrator 213, thereby closing the loop and a second multiplier 222 multiplies the estimated rotational angle error signal Δθ by a damping constant 2ϑω0 to generate the dampened version 2ϑω0Δθ of the estimated rotation angle error signal Δθ.

For example, the resolver-to-digital converter elements to the left of the sinc filters 208, 209 are implemented in software, with the sinc filters 208, 209 and DS-ADCs 203, 204 implemented in hardware.

A resolver-to-digital converter as for example described with reference to FIG. 2 can provide highly accurate estimates of angular position and angular as long as the sine signal and cosine signal provided by the resolver are not distorted in the frequency band of interest, i.e. have a clean frequency spectrum according to a sine envelope and a cosine envelope of the carrier signal, respectively. Since the state observer, as illustrated in FIG. 2, does not filter out noise in the frequency band of interest, disturbances of the since signal and cosine signal may lead to deviations of the angular position estimates and speed estimates from the true values whose size is unacceptable for exact motor control (and thus e.g. for an electric car manufacturer).

However, to provide measurement signals (sine signal and cosine signal) of sufficient quality to in turn allow the state observer to provide accurate estimates requires the provision of a high-quality resolver which may also not be desirable due to cost.

In view of the above, according to various embodiments, the state observer is enhanced based on artificial intelligence, i.e. a machine learning model, in particular a neural network having an autoencoder structure (i.e. architecture), to enable it to provide accurate estimates of angular position or rotational speed when provided with measurement signals of poor quality (i.e. e.g. in-band distortions). In the above example of a resolver-based measurement and estimation these refer to the sine signal and cosine signal but other implementations are possible which have other measurement signals, e.g. demodulated sine of cosine signal or angle signal results of magnetic or inductive based sensors with integrated circuits. Also encoder based position sensors can be supported by applying the observer on the angle results coming from any kind of position sensor.

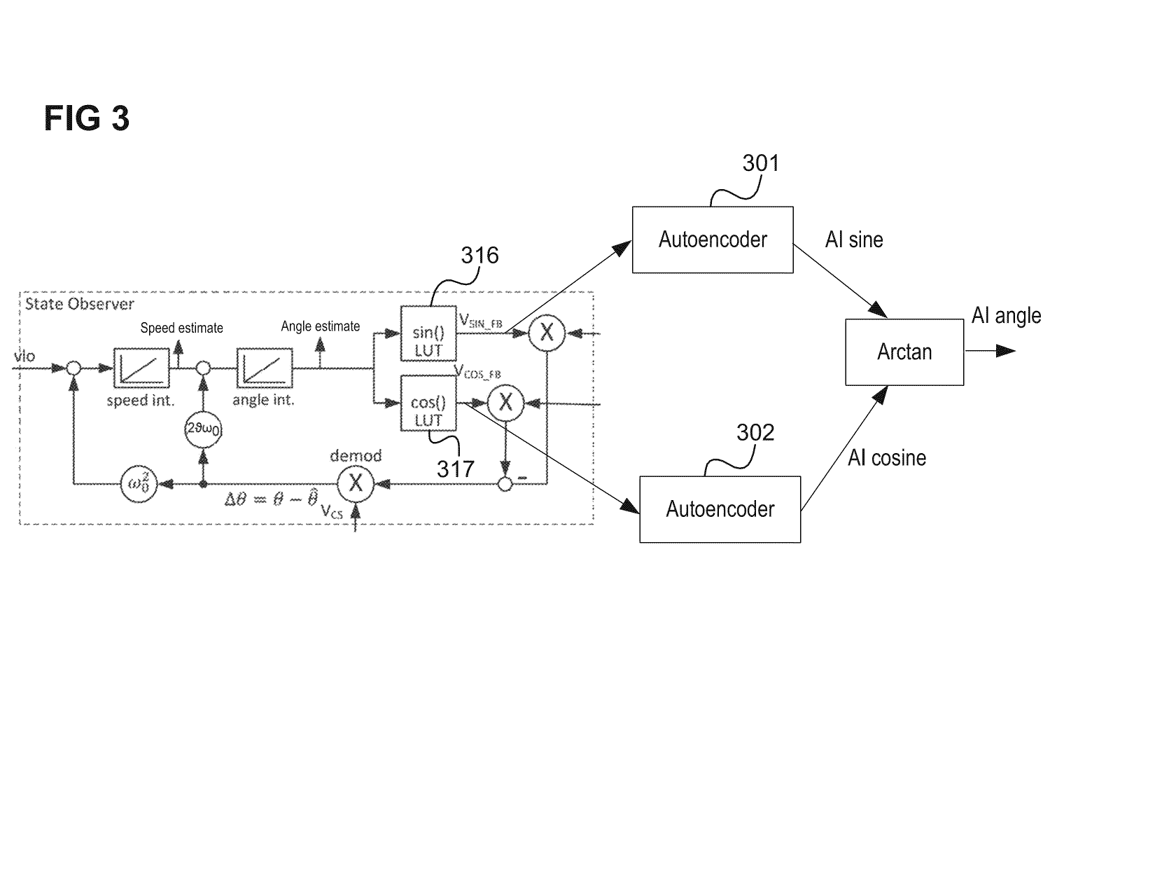

Such a machine-learning model (referred to as autoencoder in the following since it has an autoencoder structure) may be included in the resolver-to-digital converter at various positions, as illustrated in FIG. 3 to 6.

FIG. 3 illustrates an embodiment where a first autoencoder 301 is arranged at the output of the sine LUT 316 (corresponding to the sine LUT 216) and a second autoencoder 302 is arranged at the output of the cosine LUT 317 (corresponding to the cosine LUT 217). Thus, the first autoencoder 301 provides a series of “AI sine” values and the second autoencoder 302 provides a series of “AI cosine” values which can be seen as a filtered or de-noised version of the FB sine signal (or observer sine signal) and the FB cosine signal (or observer cosine signal), respectively.

Applying arctan to each pair of AI sine value and AI cosine value them gives an “AI angle”, i.e. an AI based angle estimate which may be used for motor control. In other words, the look-up table outputs of the observer are post-processed by a deep learning network.

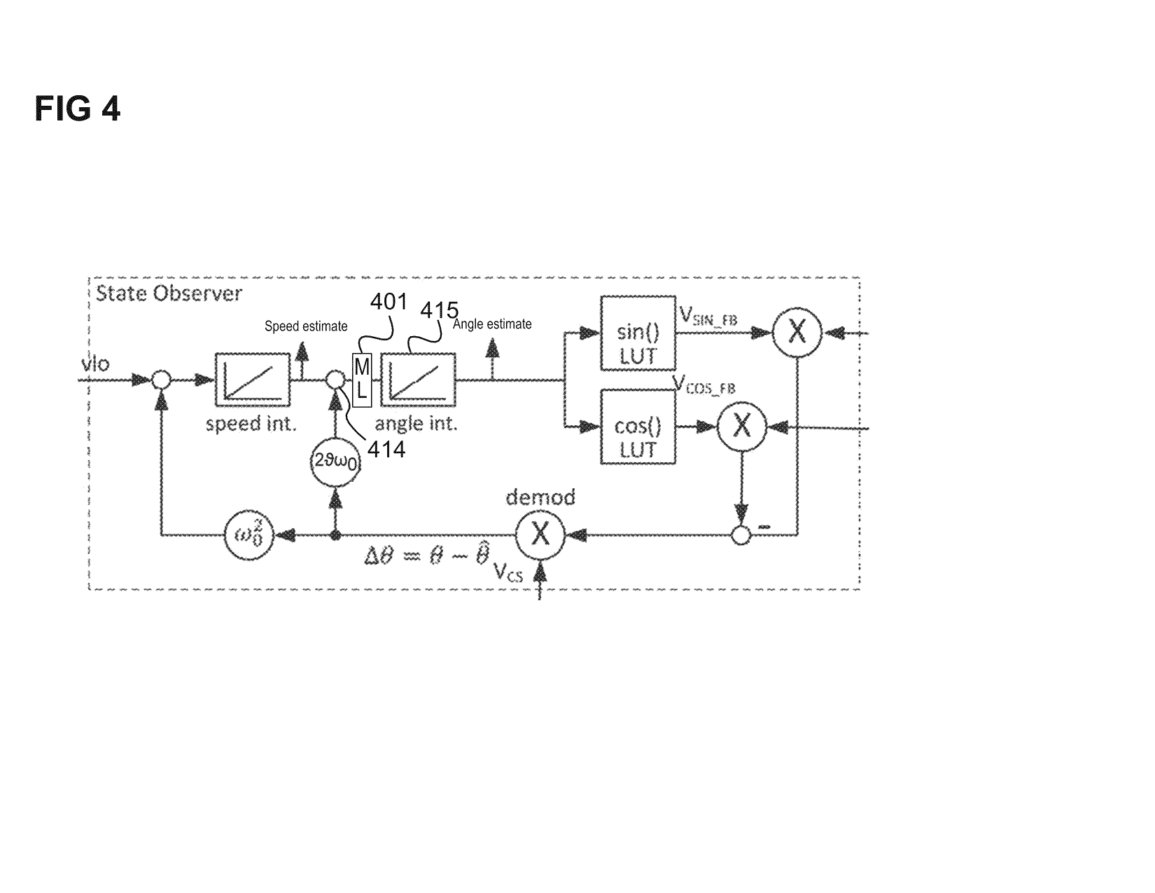

Alternatively, the autoencoder may be integrated into the observer structure (while keeping the overall observer structure), i.e. in the loop formed by the state observer, to reduce or remove the impact of in-band noise, as illustrated in FIGS. 4 to 6.

FIG. 4 illustrates an embodiment where an autoencoder 401 is arranged between the first adder 414 (corresponding to the first adder 214) and the rotation angle integrator 415 (corresponding to the rotation angle integrator 215). Thus, autoencoder 401 filters (or de-noises) the series of (offset versions of) rotation speed values (offset by the first adder 414) supplied to the rotation angle integrator 415.

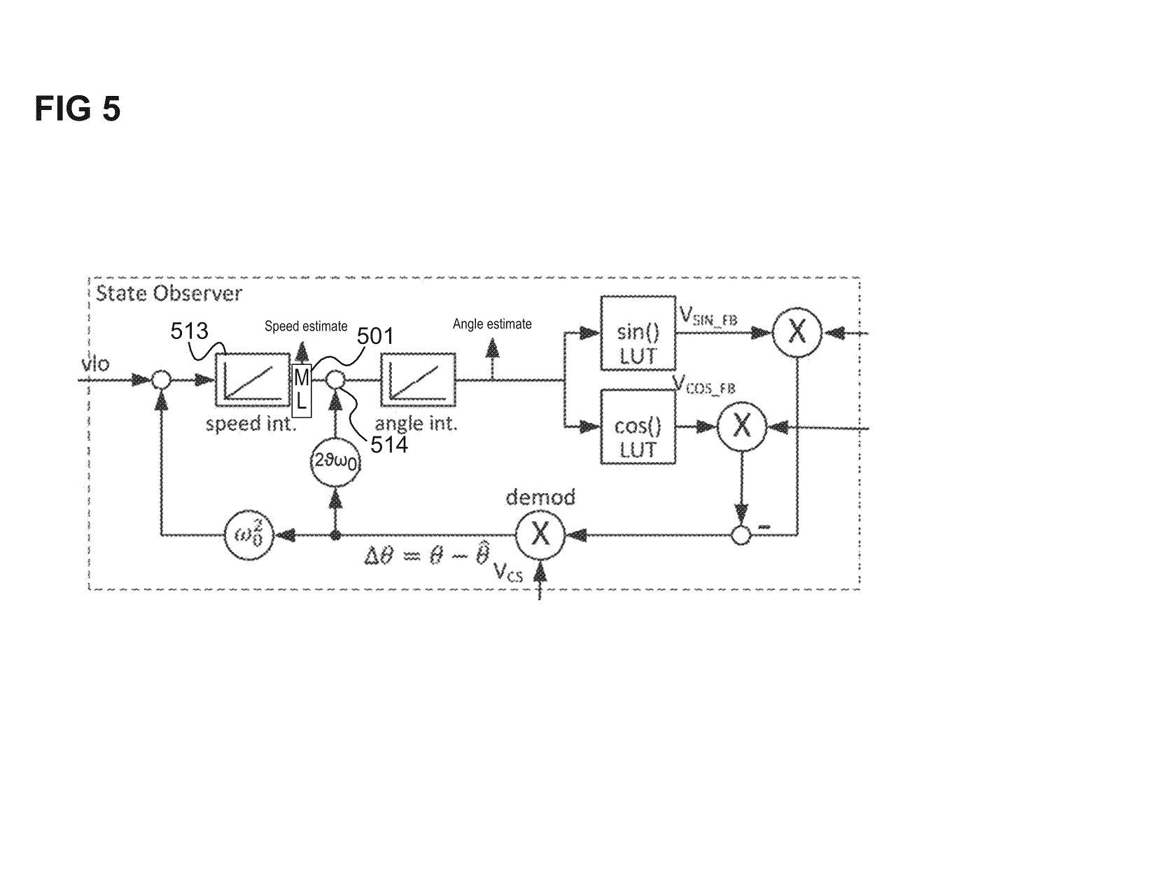

FIG. 5 illustrates an embodiment where an autoencoder 501 is arranged between the rotation speed integrator 513 (corresponding to the rotation speed integrator 213) and the first adder 514 (corresponding to the first adder 214). Thus, autoencoder 501 filters (or de-noises) the series of rotation speed values supplied to the first adder 514 (also the filtered rotation speed values may be the ones which are output as speed estimates).

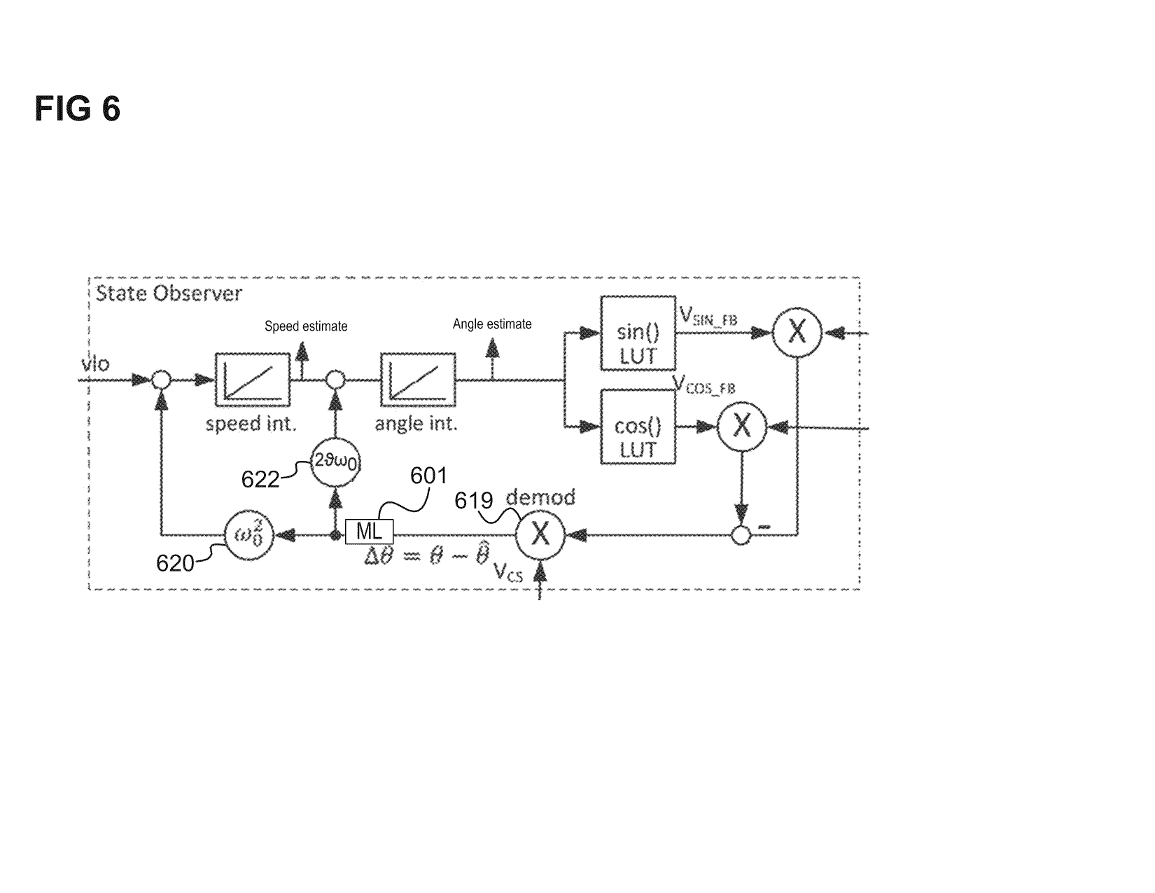

FIG. 6 illustrates an embodiment where an autoencoder 601 is arranged between the demodulator 619 (corresponding to demodulator 219) and the multipliers 620, 622 (corresponding to the multipliers 220, 222). Thus, autoencoder 401 filters (or de-noises) the series of rotational angle error estimates supplied to the multipliers 620, 622.

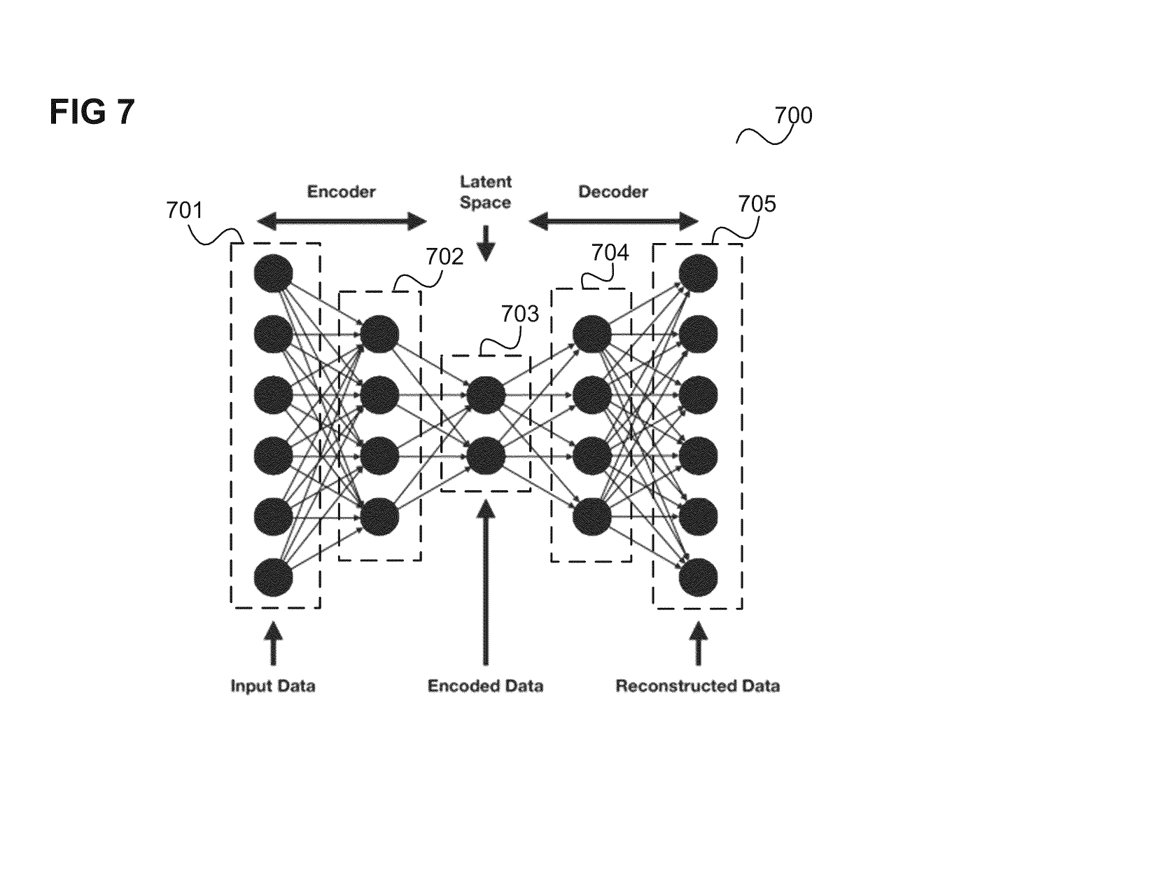

As described in the above embodiments, the autoencoder processes a time series of values (wherein the type of the values depends on where it is arranged) and outputs a time series of filtered (or de-noised) values. This is explained in more detail in the following with reference to FIG. 7.

FIG. 7 shows a machine learning model 700, specifically a neural network, corresponding to the autoencoders in the examples above.

The machine learning model 700 machine learning model includes an input layer 701 comprised of nodes (shown as circles) interconnected (e.g., in this example fully connected) with nodes forming a first hidden layer 702.

The input layer 701 includes nodes (e.g., 32 nodes) that receive input data, wherein each node receives a value of a window (of a length corresponding to the number of the nodes of the input layer) of a time series. For example, the topmost node gets a current value of the time series, the second node from the top gets the previous value of the time series and so on such that, in each time step (i.e. each estimation cycle performed by the state observer) the most recent time series values (in a certain observation window, e.g. of length 32) are fed to the machine learning model 700. The type of value depends on where the machine learning model 700 is arranged in the state observer. For example, in the example of FIG. 3, with the autoencoder 301 corresponds to the ML model 700, the ML model 700 processes the recent (e.g. 32) FB sine values provided by the sine LUT 316.

The machine learning model 700 has an autoencoder structure (i.e. an autoencoder architecture) where in this example, the encoder part has only a single hidden layer 702, i.e. the output of the hidden layer 702 is a latent representation 703 of the input data in a latent space. The latent representation 703 is compressed with respect to the input data (i.e. is a vector of less values (e.g. 16 values) than the (e.g. 32) values of the input data) and can be seen as encoded data.

It should be noted that 32 input values are only an example, and more input values can be used, e.g. 201 input values. The latent representation 703 may in such a case have for example 50 or 100 values.

In the example of FIG. 7, the decoder also only comprises a single hidden layer (second hidden layer 704) and an output layer 705 (like in the encoder part fully connected). The second hidden layer 704 and the output layer 705 decode encoded data.

The autoencoder may also have more than one hidden layer on the encoder side or the decoder side.

An autoencoder is typically trained to reproduce the input data, i.e. the output data should match the input data. However, according to various embodiments, the machine learning model is used, as described above, as a filter or noise remover. Accordingly, it is trained from training data, wherein each training example includes as input data a vector (section of a time series) corrupted by noise and the autoencoder is trained to reconstruct the vector without the noise. In other words, rather than reconstructing the input data, the autoencoder is trained to reconstruct the original vector before it has been corrupted by noise. Training examples can be generated easily by generating time series as they may occur at the position in the observer where the autoencoder is arranged, taking sections of them, adding random noise to the sections to receive corrupted versions and train the autoencoder to reconstruct the original sections from their corrupted versions. This can be done by feeding batches of the corrupted versions to the machine learning model, calculating, for each corrupted version, a loss between the original version and the reconstruction provided by the machine learning model, generating a total loss by summing over the losses and adjusting the machine learning model (i.e. its weights) to reduce the loss (by backpropagation of the total loss)

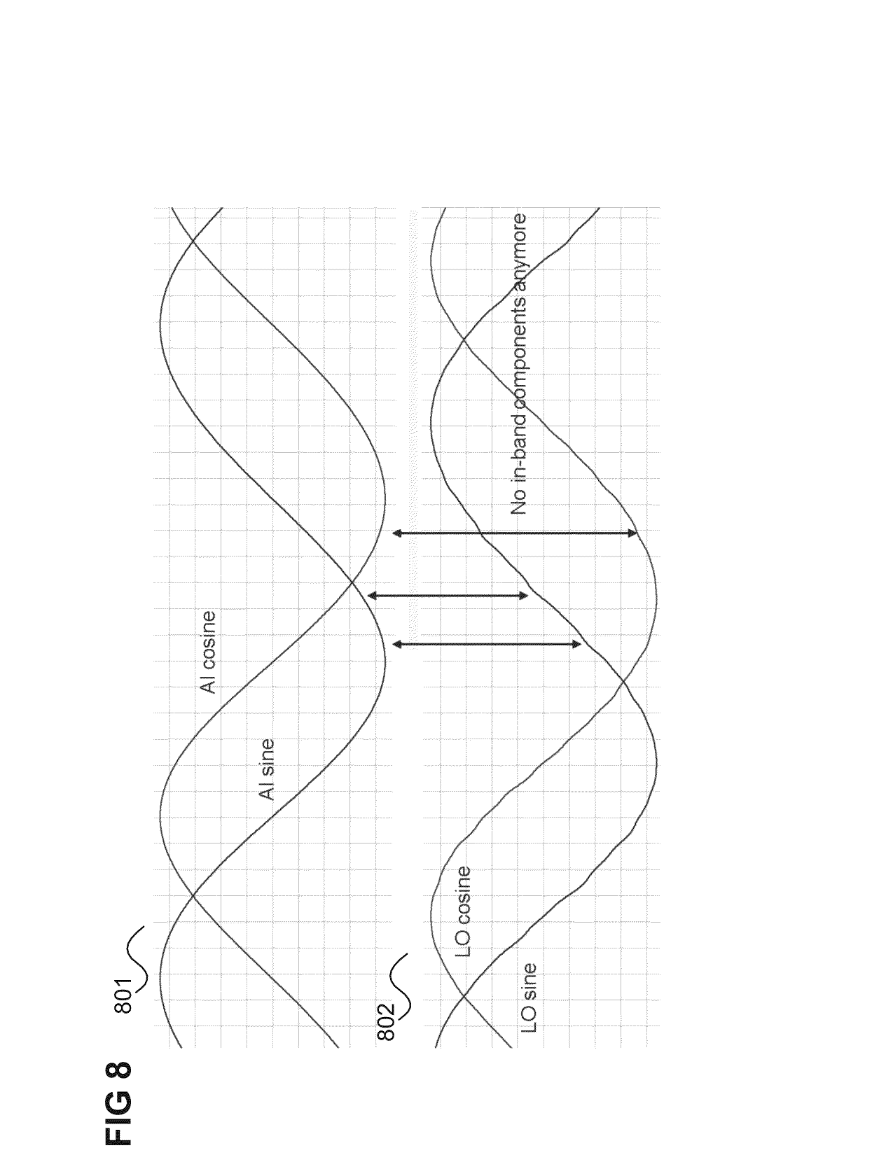

In operation, the value that the decoder provides for the current input value (i.e. e.g. the topmost value if the same order of input nodes and output nodes is used, e.g. from top to bottom) is used. So, in the example of FIG. 3, the autoencoder 301 provides a vector of output values and the one corresponding to the most recent value in the input vector of the autoencoder 301 is used as input for the AI angle calculation. In other words, the machine learning model considers the current value and a set of most recent values to provide a filtered version of the current value (in fact filtered versions of all input values but only the one corresponding to the current value is then used). So, in the example of FIG. 3, the machine learning model generates in-band noise free since and cosine time series. This is illustrated in FIG. 8.

FIG. 8 shows two diagrams 801, 802, where the bottom diagram 802 illustrates the sine and cosine as output by the LUTs 316, 317 and the top diagram illustrates the filtered sine and cosine produced by the autoencoders 301, 302, respectively. It can be seen that autoencoders 301, 302 achieve a filtering which removes in-band components.

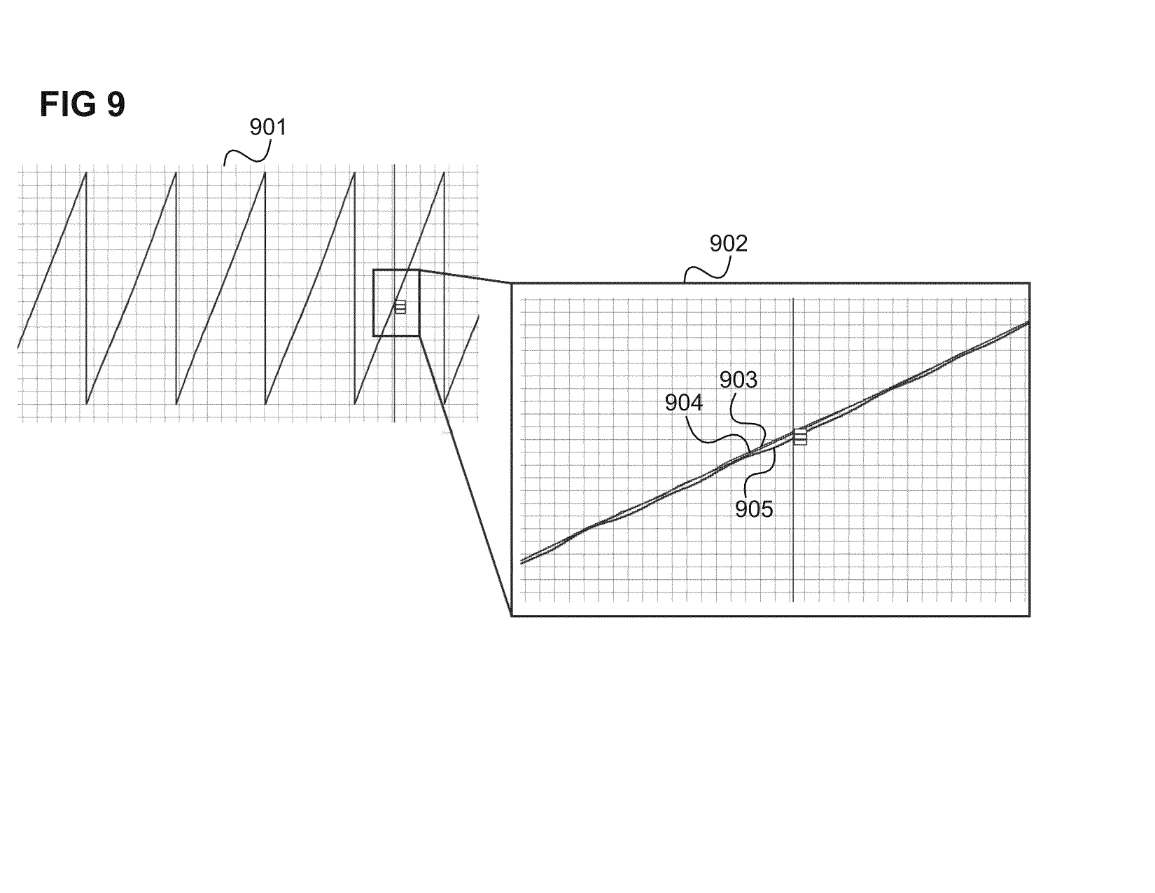

FIG. 9 illustrates the improvement of angle estimation that can be achieved with a filtering of sine and cosine as illustrated in FIG. 8.

The angle has a sawtooth waveform 901 since it linearly increases from 0 degree to 360 degree and then starts again from 0 degree. In a magnified view 902 it can be seen that the estimates generated from the outputs of the autoencoders 301, 302 (by applying arctan) are very close to the ideal angle reference (two curves 903, 904 which are very close to each other, the one (903) corresponding to the estimates generated from the autoencoder outputs is at least at some positions, slightly above the reference). A third curve 905 illustrates the angle estimates from the original LUT outputs. It can be seen that the third curve 905 has a much larger and varying deviation from the reference (up to +/- 1 degree) which may be unacceptable for a motor controller having high requirements.

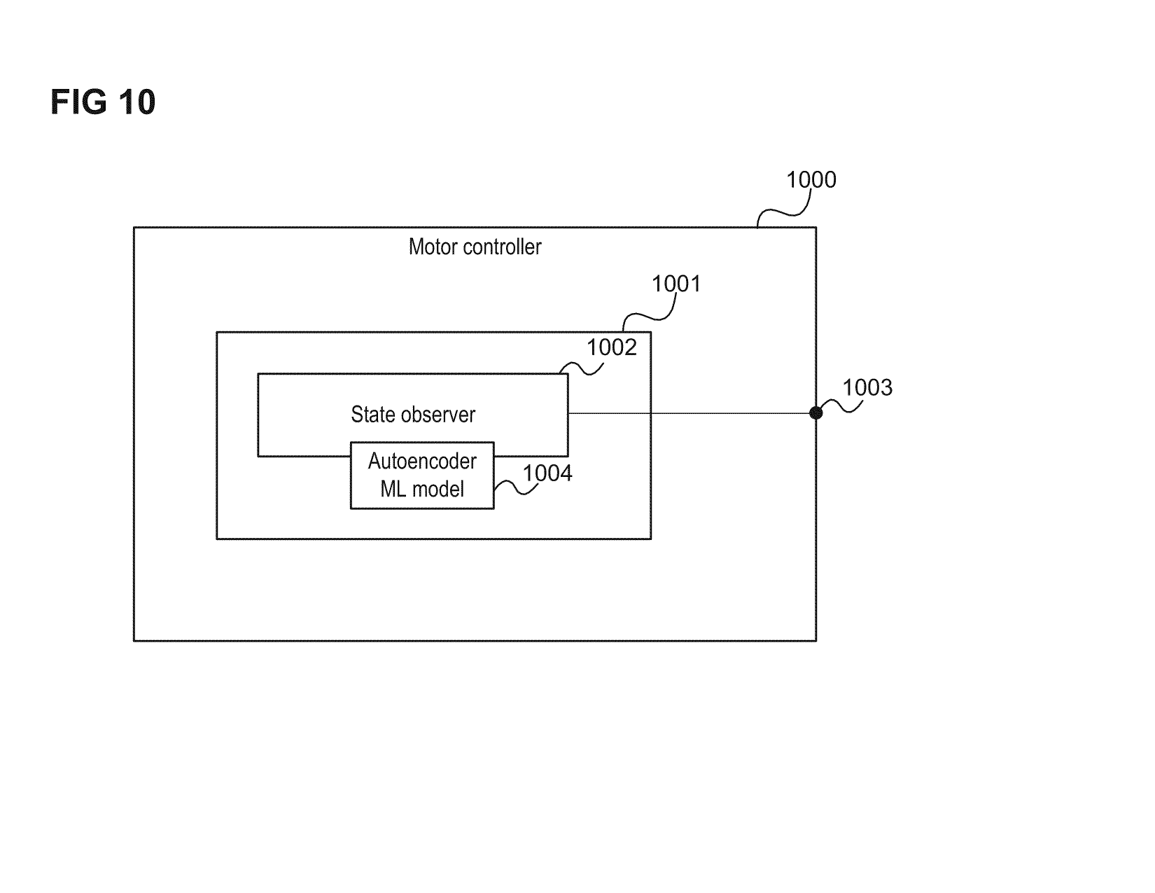

In summary, according to various embodiments, a motor controller is provided as illustrated in FIG. 10.

FIG. 10 shows a motor controller 1000 according to an embodiment.

The motor controller 1000 comprises an estimation circuit 1001 (which may also be at least partially implemented in software running, e.g. on a digital signal processor) configured to implement a state observer 1002 (i.e. a Luenberger observer).

The motor controller 1000 further comprises an input 1003 configured to receive measurements representing a sequence of motor shaft angles of a motor and to supply the measurements to the state observer 1002.

The estimation circuit 1001 is configured to perform motor shaft angle or motor shaft rotation speed estimation by

generating, by means of the state observer 1002, a time series representing motor shaft angle estimates, motor shaft rotation speed estimates or motor shaft angle estimation errors from the measurements

filtering the generated time series by a machine learning model 1004 having an autoencoder architecture and

generating one or more estimates of the motor shaft angle or the motor shaft rotation speed from the filtered time series.

According to various embodiments, in other words an ML model (e.g. a neural network) with an autoencoder structure, i.e. with an encoder part and a decoder part, where the encoder part can be seen to extract features to compress input data and thus create a bottleneck, is used to provide a “clean” version of a time series that is used within or is generated by an estimation loop. Due to the compression, unnecessary or undesired information, in particular noise, is filtered out. So, an autoencoder ML model is used as a filter or de-noiser in a motor shaft angle position or motor shaft angle rotation speed estimation.

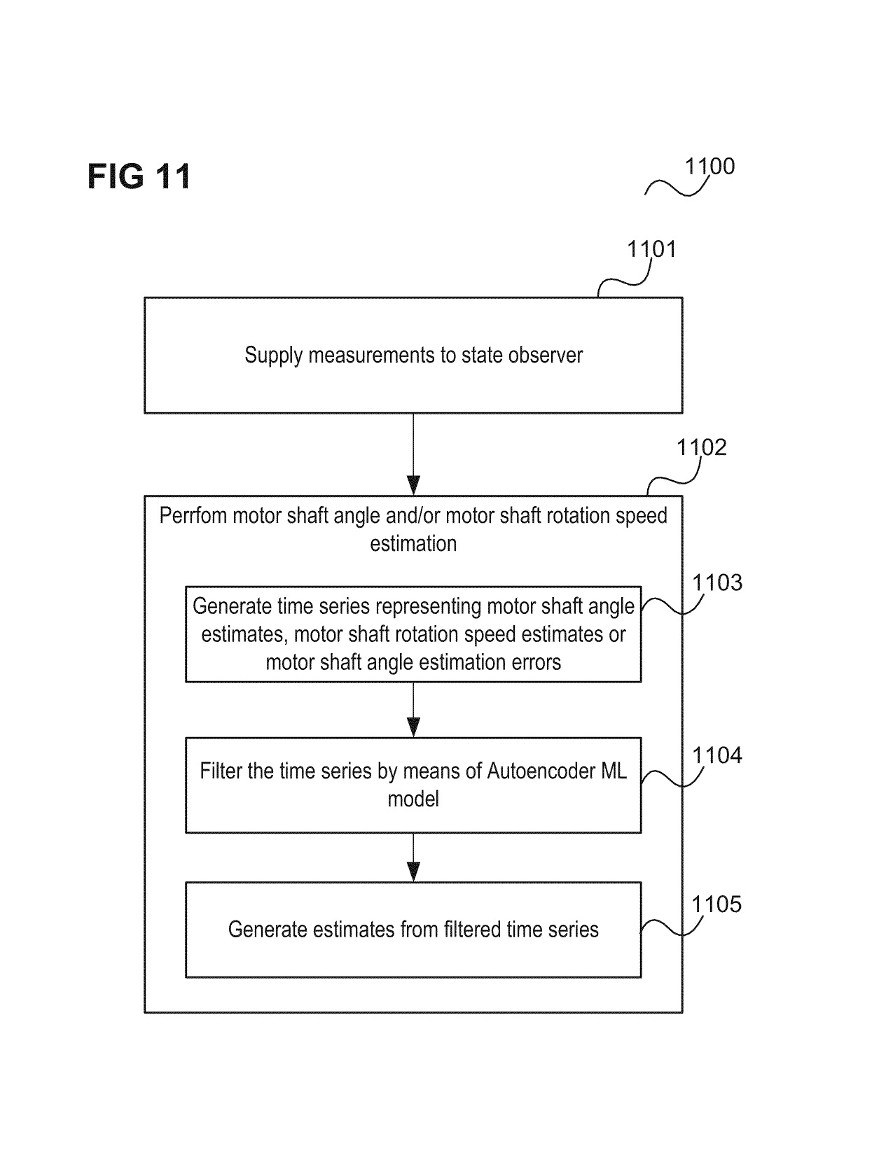

According to various embodiments, a method as illustrated in FIG. 11 is performed (e.g. by a motor controller or motor arrangement).

FIG. 11 shows a flow diagram 1100 illustrating a method for estimating a motor shaft angle or a motor shaft rotation speed of a motor.

In 1101, measurements representing a sequence of motor shaft angles of a motor are supplied to a state observer.

In 1102, motor shaft angle or motor shaft rotation speed estimation is performed by

generating, in 1103, by means of the state observer, a time series representing motor shaft angle estimates, motor shaft rotation speed estimates or motor shaft angle estimation errors from the measurements

filtering, in 1104, the generated time series by a machine learning model having an autoencoder architecture and

generating, in 1105, one or more estimates of the motor shaft angle or the motor shaft rotation speed from the filtered time series.

It should be noted that the supply of measurements and performing the estimation may run in parallel, i.e. the estimation is typically performed while new measurements are being supplied.

Similarly 1103, 1104, 1105 are not performed for all values one after the other but value by value, i.e. e.g. a new value of the time series is generated (for a current time step), the time series (with that value as newest value) is filtered (e.g. considering a certain number of past time series values, i.e. over a certain time window) and a new estimate is generated from the filtering result for the current time step.

### Various Examples are described in the following

Example 1 is a motor controller as described with reference to FIG. 10.

Example 2 is the motor controller of example 1, wherein the machine learning model is trained for de-noising time series input to it.

Example 3 is the motor controller of example 1 or 2, wherein the motor controller is configured to control the motor using the one or more estimates.

Example 4 is the motor controller of any one of examples 1 to 3, wherein the motor controller is configured to perform closed-loop control of the motor using the one or more estimates.

Example 5 is the motor controller of any one of examples 1 to 4, wherein the motor controller is configured to perform real-time control of the motor using the one or more estimates.

Example 6 is the motor controller of any one of examples 1 to 5, wherein filtering the generated time series comprises feeding, for an input length of the machine learning model, sections of the time series with the input length to the machine learning model (i.e. filtering is performed section by section).

Example 7 is the motor controller of example 6, wherein each section of the time series comprises the most recent values of the time series.

Example 8 is the motor controller of any one of examples 1 to 7, wherein generating the one or more estimates of the motor shaft angle or the motor shaft rotation speed from the filtered time series comprises generating the one or more estimates from a value output by the machine learning model for the most recent value of the time-series.

Example 9 is the motor controller of any one of examples 1 to 8, wherein the generated time series is a time series of values indicating errors between estimates of the sequence of motor shaft angles and the sequence of motor shaft angles.

Example 10 is the motor controller of any one of examples 1 to 9, wherein the generated time series is a time series of sines or a time series of cosines of angle estimates.

Example 11 is the motor controller of any one of examples 1 to 10, wherein the generated time series is a time series of speed estimates

Example 12 is the motor controller of any one of examples 1 to 11, wherein the state observer implements a loop (e.g. denoted as filter chain loop) and the machine learning model is arranged in the loop.

Example 13 is the motor controller of any one of examples 1 to 12, wherein the state observer is configured to perform estimation cycles, wherein it generates a motor shaft angle estimate or a motor shaft rotation speed estimate in each estimation cycle and the estimation circuit applies the machine learning model to filter a respective version of the time series in each estimation cycle (i.e. inference is performed in each estimation cycle).

Example 14 is a method as described with reference to FIG. 11.

Example 15 is the method of example 14, wherein the machine learning model is trained from training examples, each including, as target output, a respective time series and, as training input, a respective version of the time series affected by noise (i.e. a disturbed version).

It should be noted that examples and embodiments described in context with the motor controller are analogously valid for the method for estimating a motor shaft angle or a motor shaft rotation speed of a motor and vice versa.

Although specific embodiments have been illustrated and described herein, it will be appreciated by those of ordinary skill in the art that a variety of alternate or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

### REFERENCE SIGNS

100 Motor control arrangement

101 Resolver rotor

102 Resolver

103 Motor

104 Motor rotor

105 Microcontroller

106 Resolver-to-digital converter

107 Carrier signal generator

108 PWM generator

201 Resolver-to-digital converter

202 Filter chain loop

203, 204 ADCs

205 Resolver

206, 207 Mixers

208, 209 Sinc Filters

210 Gain adjuster

211 Carrier signal generator

212 State observer

213 Rotation speed integrator

214 Adder

215 Rotation angle integrator

216 Sine LUT

217 Cosine LUT

218 Subtractor

219 Demodulator

220 Multiplier

221 Adder

222 Multiplier

301, 302 Autoencoders

316 Sine LUT

317 Cosine LUT

401 Autoencoder

414 Adder

415 Rotation angle integrator

501 Autoencoder

513 Rotation speed integrator

514 Adder

601 Autoencoder

619 Demodulator

620, 622 Multipliers

700 ML model

701 Input layer

702 Hidden layer

703 Latent Representation

704 Hidden layer

705 Output layer

801, 802 Diagrams

901 Sawtooth waveform

902 Magnified view

903-905 Curves

1000 Motor controller

1001 Estimation circuit

1002 State observer

1003 Input

1004 ML model

1100 Flow diagram

1101-1105 Processing

What is claimed is:

1. A motor controller, comprising:
an estimation circuit configured to implement a state observer;
an input configured to receive measurements representing a sequence of motor shaft angles of a motor and to supply the measurements to the state observer; and
wherein the estimation circuit is configured to perform motor shaft angle or motor shaft rotation speed estimation by
generating, by means of the state observer, a time series representing motor shaft angle estimates, motor shaft rotation speed estimates or motor shaft angle estimation errors from the measurements;
filtering the generated time series by a machine learning model having an autoencoder architecture; and
generating one or more estimates of the motor shaft angle or the motor shaft rotation speed from the filtered time series.

2. The motor controller of claim 1, wherein the machine learning model is trained for de-noising time series input to it.

3. The motor controller of claim 1, wherein the motor controller is configured to control the motor using the one or more estimates.

4. The motor controller of claim 1, wherein the motor controller is configured to perform closed-loop control of the motor using the one or more estimates.

5. The motor controller of claim 1, wherein the motor controller is configured to perform real-time control of the motor using the one or more estimates.

6. The motor controller of claim 1, wherein filtering the generated time series comprises feeding, for an input length of the machine learning model, sections of the time series with the input length to the machine learning model.

7. The motor controller of claim 6, wherein each section of the time series comprises the most recent values of the time series.

8. The motor controller of claim 1, wherein generating the one or more estimates of the motor shaft angle or the motor shaft rotation speed from the filtered time series comprises generating the one or more estimates from a value output by the machine learning model for the most recent value of the time series.

9. The motor controller of claim 1, wherein the generated time series is a time series of values indicating errors between estimates of the sequence of motor shaft angles and the sequence of motor shaft angles.

10. The motor controller of claim 1, wherein the generated time series is a time series of sines or a time series of cosines of angle estimates.

11. The motor controller of claim 1, wherein the generated time series is a time series of speed estimates.

12. The motor controller of claim 1, wherein the state observer implements a loop and the machine learning model is arranged in the loop.

13. The motor controller of claim 1, wherein the state observer is configured to perform estimation cycles, wherein the state observer generates a motor shaft angle estimate or a motor shaft rotation speed estimate in each estimation cycle and the estimation circuit applies the machine learning model to filter a respective version of the time series in each estimation cycle.

14. A method for estimating a motor shaft angle or a motor shaft rotation speed of a motor, comprising:
supplying measurements representing a sequence of motor shaft angles of a motor to a state observer; and
performing motor shaft angle or motor shaft rotation speed estimation by
generating, with the state observer, a time series representing motor shaft angle estimates, motor shaft rotation speed estimates or motor shaft angle estimation errors from the measurements;
filtering the generated time series by a machine learning model having an autoencoder architecture; and
generating one or more estimates of the motor shaft angle or the motor shaft rotation speed from the filtered time series.

15. The method of claim 14, wherein the machine learning model is trained from training examples, each including, as target output, a respective time series and, as training input, a respective version of the time series affected by noise.

16. A motor controller, comprising:
an estimation circuit configured to
receive measurements representing a sequence of motor shaft angles of a motor;
based on the measurements, generate a time series representing motor shaft angle estimates, motor shaft rotation speed estimates or motor shaft angle estimation errors;
filter the generated time series using a machine learning model having an autoencoder architecture;
generating one or more estimates of the motor shaft angle or the motor shaft rotation speed from the filtered time series; and
provide the one or more estimates of the motor shaft angle or the motor shaft rotation speed to a state observer for use in estimating motor shaft angle estimates, motor shaft rotation speed estimates or motor shaft angle estimation errors.

17. The motor controller of claim 16, wherein the machine learning model is trained for de-noising an input time series.

18. The motor controller of claim 16, wherein the motor controller is configured to control the motor using the one or more estimates.

19. The motor controller of claim 16, wherein generating the one or more estimates of the motor shaft angle or the motor shaft rotation speed from the filtered time series comprises generating the one or more estimates from a value output by the machine learning model for the most recent value of the time series.

20. The motor controller of claim 16, wherein the state observer is configured to perform estimation cycles, wherein the state observer generates a motor shaft angle estimate or a motor shaft rotation speed estimate in each estimation cycle and the estimation circuit applies the machine learning model to filter a respective version of the time series in each estimation cycle.
